(19) United States
(12) Patent Application Publication
(10) Pub. No.: US 2004/0263215 A1
(43) Pub. Date: Dec. 30, 2004

(54) Voltage detector

(75) Inventor: Meng-Jyh Lin, Hsinchu City (TW)

Correspondence Address: BACON & THOMAS, PLLC, 625 SLATERS LANE, FOURTH FLOOR, ALEXANDRIA, VA, 22314

(73) Assignee: Sunplus Technology Co., Ltd., Hsinchu (TW)

(21) Appl. No.: 10/799,708

(22) Filed: Mar. 15, 2004

(30) Foreign Application Priority Data
Jun. 30, 2003 (TW) 092117880

(51) Int. Cl. H03K 5/153

(52) U.S. Cl. 327/77

(57) ABSTRACT

A voltage detector is disclosed, which has a resistor pair, a reference resistor, at least one transistor pair and a comparator. One resistor of the resistor pair is coupled between an input voltage and one of the transistor pair, and the other resistor is coupled between the input voltage and the reference resistor. The other transistor is coupled between the reference resistor and a ground voltage. Thus, a reference detection voltage and a voltage to be detected are generated. The comparator compares the reference detection voltage and the voltage to be detected to obtain a resulting output, wherein temperature effect can be eliminated by adjusting an area ratio of the transistors and an area ratio of the reference resistor to the resistor pair.

### BACKGROUND OF THE INVENTION

1. Field of the Invention

The present invention relates to a voltage detector and, more particularly, to a voltage detector not affected by temperatures and operating voltages.

2. Description of Related Art

FIG. 1 is a schematic diagram of a typical voltage detector. In FIG. 1, the voltage detector essentially includes resistors 11-13, a transistor 14 and a comparator 15. The resistors 11, 12 are a pair and the resistor 13 is a reference resistor. When a voltage

$$Vin \frac{R3}{R2 + R3}$$

generated by an input voltage Vin through the resistors 12, 13 is smaller than the emitter-base voltage V_{EB} of the transistor 14, the comparator 15 outputs a high voltage V_{DD}. When the voltage

$$Vin \frac{R3}{R2 + R3}$$

generated by the input voltage Vin through the resistors 12, 13 is greater than the emitter-base voltage V_{EB} of the transistor 14, the comparator 15 outputs a low voltage GND.

However, the emitter-base voltage V_{EB} of the transistor 14 has a feature of negative temperature coefficient; i.e., the voltage reduces as the temperature increases. In addition, it varies with operating voltages. Thus, temperature and resistance (R1) changes will vary the detection voltage level. However, such a change is not allowable to many applications.

FIG. 2 is a schematic diagram of another typical voltage detector. In FIG. 2, the detector includes a bandgap reference generator 21, resistors (R2, R3) 22, 23 and a comparator 24. The bandgap reference generator 21 generates a bandgap reference voltage V_{BG}, wherein the bandgap reference voltage will not vary with temperatures and operating voltages. The comparator 24 can compare the bandgap reference voltage and the voltage

$$Vin \frac{R3}{R2 + R3} ,$$

and thus the detection voltage level is

$${V}_{BG} \frac{R2 + R3}{R3} .$$

Accordingly, when the detection voltage has a level higher than the bandgap reference voltage, a voltage level can be detected.

FIG. 3 is a schematic diagram of the internal circuit of the bandgap reference generator 21 of FIG. 2. In FIG. 3, the generator 21 includes resistors (R1A, R2A, R3A) 31-33, a transistor pair (Q1, Q2) having transistors 34, 35 and an operational amplifier (OP) 36. As shown in FIG. 3, the additional circuits for the bandgap reference generator 21 requires greater area ratio of transistors so that the design for such a voltage detector is complicated and such a voltage detector consumes more power.

Therefore, it is desirable to provide an improved voltage detector to mitigate and/or obviate the aforementioned problems.

### SUMMARY OF THE INVENTION

An object of the present invention is to provide a voltage detector, which is not affected by temperatures, operating voltages and resistances.

Another object of the present invention is to provide a voltage detector, which can save power.

To achieve the object, a voltage detector is provided, which includes: a resistor pair connected to an input voltage; a reference resistor connected to one resistor of the resistor pair, for partitioning the input voltage to produce a first comparison voltage; at least one transistor pair respectively connected the other resistor of the resistor pair and the reference resistor, for producing a second comparison voltage; and a comparator connected between a connection of the two pairs and a connection of the resistor pair and the reference resistor, for receiving and then comparing the first comparison voltage and the second comparison voltage, thereby outputting a voltage level.

Other objects, advantages, and novel features of the invention will become more apparent from the following detailed description when taken in conjunction with the accompanying drawings.

### BRIEF DESCRIPTION OF THE DRAWINGS

FIG. 1 is a schematic diagram of a typical voltage detector;

FIG. 2 is a schematic diagram of another typical voltage detector;

FIG. 3 is a schematic diagram of an internal circuit of a typical bandgap reference generator;

FIG. 4 is a schematic diagram of a voltage detector according to an embodiment of the invention;

FIG. 5 is a schematic diagram of a voltage detector with multiple transistor pairs according to an embodiment of the invention;

FIG. 6 is a schematic diagram of a voltage detector with a disconnection switch according to an embodiment of the invention; and

FIG. 7 is a schematic diagram of a voltage detector with multiple transistor pairs and a disconnection switch according to an embodiment of the invention.

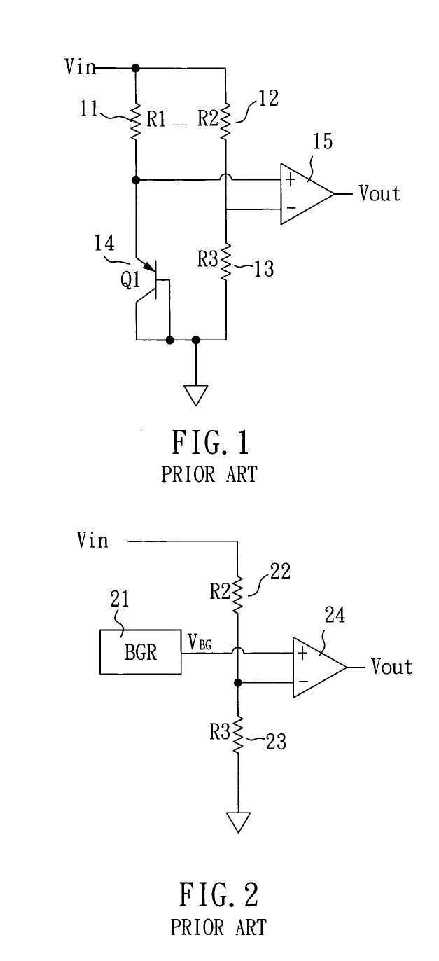

### DETAILED DESCRIPTION OF THE PREFERRED EMBODIMENT

FIG. 4 is a schematic diagram of a voltage detector according to a preferred embodiment of the invention. In FIG. 4, the voltage detector includes a resistor pair 41, a reference resistor (R3) 42, a transistor pair 43 and a comparator 44. The resistor pair 41 has resistors (R1, R2) 411, 412. The transistor pair has transistors (Q1, Q2) 431, 432. In this embodiment, the transistors 431, 432 are a BJT respectively.

The resistor pair 41 is connected to an input voltage Vin. The reference resistor 42 is connected to the resistor 412. The transistor 431 is connected to the resistor 411 and the transistor 432 is connected to the reference resistor 42. The comparator 44 has a positive input terminal connected to a connection of the resistor 411 and the transistor 431, and a negative input terminal connected to a connection of the resistor 412 and the reference resistor 42.

The connection of the devices 411 and 431 is indicated by N1 node that produces a reference detection voltage, and the connection of the devices 412 and 42 is indicated by N2 node that produces a partial input voltage to be detected. The comparator 44 compares the voltages at N1 and N2 nodes. When the partial input voltage Vin is smaller than the reference detection voltage, N2 voltage is smaller than N1 voltage; i.e., the comparator's negative input voltage is smaller than its positive input voltage. When the partial input voltage Vin is greater than the reference detection voltage, N2 voltage is greater than N1 voltage; i.e., the comparator's negative input voltage is greater than its positive input voltage. When the partial input voltage Vin equals to the reference detection voltage, N2 voltage equals to N1 voltage; i.e., the comparator's negative input voltage equals to its positive input voltage. Hence, the voltage detection can be achieved.

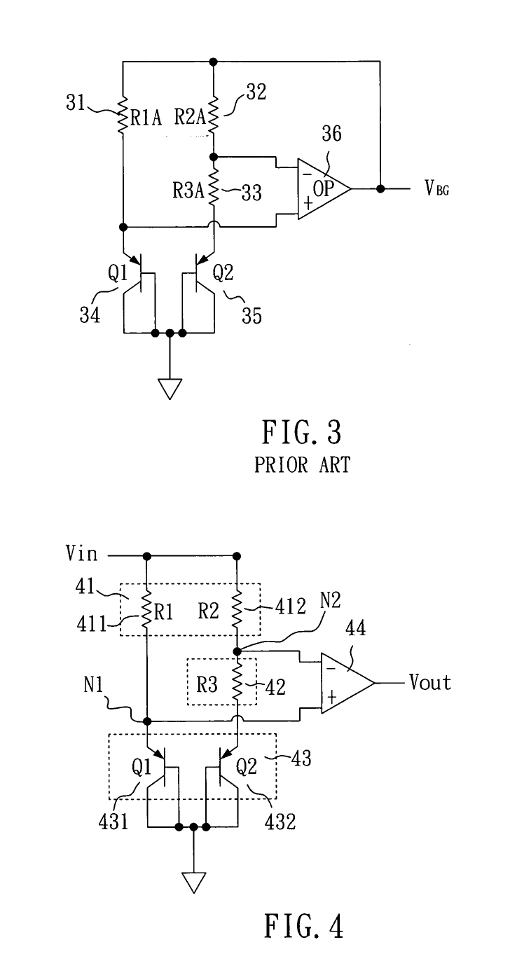

In this embodiment, temperature compensation for the reference detection voltage on N1 and the partial input voltage to be detected on N2 is similar to that for the typical bandgap reference circuit. Referring to FIG. 3, an equation for temperature compensation is given by:

$${V}_{BG} = {V}_{EB1} + ( \frac{{R}_{2}}{{R}_{3}} ) [ Δ {V}_{EB} + {V}_{OS} ] ,$$

where V_{OS} is offset voltage of operational amplifier 36, ΔV_{EB} is emitter-base voltage difference of BJT pair (Q1 and Q2) 34, 35 as:

$$Δ {V}_{EB} = {V}_{T} ln ( \frac{{R}_{2} {A}_{Q2}}{{R}_{1} {A}_{Q1}} ) ,$$

for area ratio

$$\frac{{A}_{Q2}}{{A}_{Q1}}$$

of Q1 and Q2. Accordingly we obtain:

$${V}_{BG} = {V}_{EB1} + ( \frac{{R}_{2}}{{R}_{3}} ) [ {V}_{T} ln ( \frac{{R}_{2} {A}_{Q2}}{{R}_{1} {A}_{Q1}} ) + {V}_{OS} ] , \\ where \frac{\partial {V}_{T}}{\partial T} = \frac{K}{q} = 0.087 mV \vert ° C . as {V}_{T} = \frac{kT}{q} = 26 mV \vert T = 300 ° K . \\ and \frac{\partial {V}_{EB}}{\partial T} ≅ - 2 mV \vert ° C . as {V}_{EB} = 600 mV \vert T = 300 ° K .$$

As cited, adjusting resistance ratio of the resistor 32 to resistor pair 31, 32 and area ratio of the BJT pair 34, 35 can eliminate the temperature coefficients of the bandgap reference voltage completely. Similarly, in this embodiment, adjusting resistance ratio of the reference resistor 42 to resistor pair 411, 412 (i.e., adjusting the value of reference resistor 42) and area ratio of the transistor pair 43 can eliminate temperature effect completely.

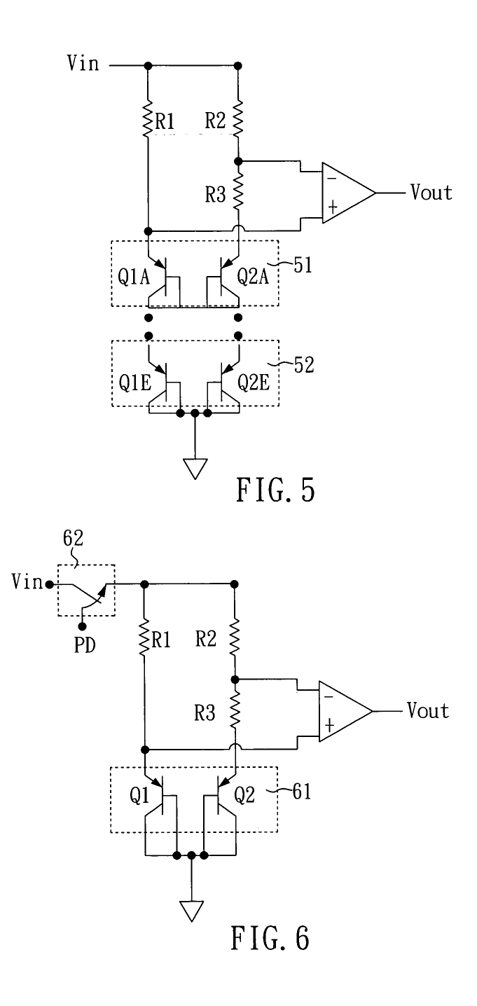

However, the partial input voltage to be detected may be much higher than the reference detection voltage and thus the voltage detection cannot be effectively performed. For this, cascaded transistor pairs 51, 52 are provided as shown in FIG. 5. The stage of cascaded transistor pairs depends on the voltage to be detected. That is, when the voltage to be detected is close to the reference detection voltage (voltage of N1 node), the number of cascaded transistor pairs is 1, which applies only one transistor pair 51. When the voltage to be detected is twice as high as the reference detection voltage (voltage of N1 node), the stage of cascaded transistor pairs is 2, which applies two transistor pairs 51, 52. Accordingly, the detection voltage can keep in a steady level.

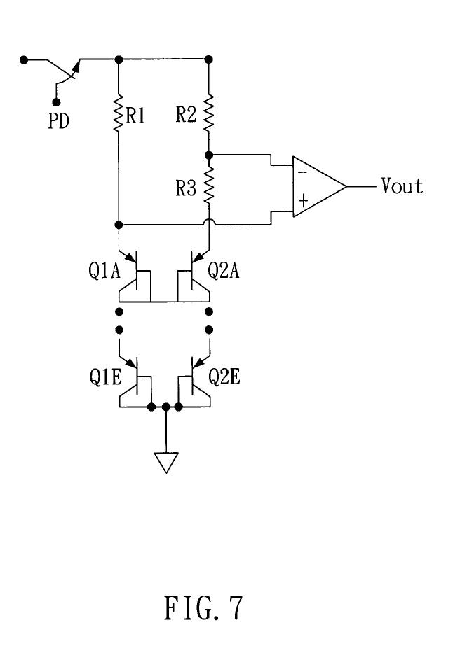

FIG. 6 is a schematic diagram of a voltage detector with a disconnection switch. As shown in FIG. 6, a disconnection switch 62 is added between a resistor pair 61 and an input voltage Vin. The disconnection switch 62 disconnects a current flow in the resistor pair 61 at no voltage detection operation, thereby entering a standby mode. Further, the disconnection switch can be added to the circuit of FIG. 5, to form a voltage detector with multiple transistor pairs and a disconnection switch as shown in FIG. 7.

As cited, the invention uses at least one-stage transistor pair, a resistor pair, a divided voltage resistor and a comparator to form the voltage detector and adjusts an area ratio of the transistor pair or a ratio of the divided voltage resistor to the resistor pair for reducing temperature coefficient impact. The voltage detector is not affected by the change of operating voltage and resistance and thus can keep a steady level to reduce temperature effect. The voltage detector is a simple circuit with low power consumption.

Although the present invention has been explained in relation to its preferred embodiment, it is to be understood that many other possible modifications and variations can be made without departing from the spirit and scope of the invention as hereinafter claimed.

What is claimed is:

1. A voltage detector, comprising:
a resistor pair connected to an input voltage;
a reference resistor connected to one resistor of the resistor pair, for partitioning the input voltage to produce a first comparison voltage;
at least one transistor pair respectively connected the other resistor of the resistor pair and the reference resistor, for producing a second comparison voltage; and
a comparator connected between a connection of the two pairs and a connection of the resistor pair and the reference resistor, for receiving and then comparing the first comparison voltage and the second comparison voltage, thereby outputting a voltage level.

2. The voltage detector as claimed in claim 1, wherein a resistance ratio of the resistor pair, a resistance of the reference resistor and an area ratio of the at least one transistor pair are adjusted to reduce temperature coefficient impact.

3. The voltage detector as claimed in claim 2, wherein the comparator has a detection voltage level as
$${V}_{BG} \frac{R2 + R3}{R3} ,$$
where V_{BG} is the second comparison voltage, R2 is a resistance of the one of the resistor pair and R3 is the reference resistor.

4. The voltage detector as claimed in claim 3, wherein the resistance ratio of the resistor pair, the resistance of the reference resistor and the area ratio of the at least one transistor pair are adjusted such that the second comparison voltage has a voltage level in the detection voltage level, thereby obtaining a required detection voltage level.

5. The voltage detector as claimed in claim 1, wherein the comparator has a detection voltage level, and a cascaded number varies with the detection voltage level such that a number of cascaded transistor pairs are added to the at least one transistor pair based on the cascaded number.

6. The voltage detector as claimed in claim 5, wherein the number of cascaded transistor pairs is two when the detection voltage has twice level as high as the second comparison voltage.

7. The voltage detector as claimed in claim 1, further comprising: a disconnection switch coupled between the resistor pair and the input voltage, for disconnecting a current flow in the resistor pair and thus entering a standby mode.
